(19) United States
(12) Patent Application Publication
(10) Pub. No.: US 2024/0290387 A1
(43) Pub. Date: Aug. 29, 2024

(54) Memory Circuitry And Methods Used In Forming Memory Circuitry

(71) Applicant: Micron Technology, Inc., Boise, ID (US)

(72) Inventor: Gianpietro Carnevale, Bottanuco (IT)

(73) Assignee: Micron Technology, Inc., Boise, ID (US)

(21) Appl. No.: 18/584,502

(22) Filed: Feb. 22, 2024

Related U.S. Application Data
(60) Provisional application No. 63/448,455, filed on Feb. 27, 2023.

(51) Int. Cl. G11C 16/04; H10B 41/10; H10B 41/27; H10B 41/35; H10B 43/10; H10B 43/27; H10B 43/35

(52) U.S. Cl. CPC G11C 16/0483; H10B 41/10; H10B 41/27; H10B 41/35; H10B 43/10; H10B 43/27; H10B 43/35

(57) ABSTRACT

A method used in forming memory circuitry comprises forming a stack comprising vertically-alternating different-composition first tiers and second tiers. Channel-material strings extend through the first and second tiers. The channel material of an upper portion of the channel-material strings is part of individual select-gate transistors in a finished-circuitry construction. A lower portion of the channel-material strings is part of memory-cell strings in the finished-circuitry construction. The upper portion of the channel-material strings individually comprise a cylinder comprising the channel material of the individual select-gate transistors. A mid-material is formed within an internal volume of the cylinder radially-inside of the channel material. The mid-material material comprises conductivity-increasing dopant therein. The conductivity-increasing dopant is out-diffused from the mid-material into the channel material of the cylinder and the individual select-gate transistors. The mid-material is insulative or semiconductive in the finished-circuitry construction. Other embodiments, including structure independent of method, are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A field effect transistor is one type of electronic component that may be used in a memory cell. These transistors comprise a pair of conductive source/drain regions having a semiconductive channel region there-between. A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate.

Flash memory is one type of memory and has numerous uses in modern computers and devices. For instance, modern personal computers may have BIOS stored on a flash memory chip. As another example, it is becoming increasingly common for computers and other devices to utilize flash memory in solid state drives to replace conventional hard drives. As yet another example, flash memory is popular in wireless electronic devices because it enables manufacturers to support new communication protocols as they become standardized, and to provide the ability to remotely upgrade the devices for enhanced features.

NAND may be a basic architecture of integrated flash memory. A NAND cell unit comprises at least one selecting device coupled in series to a serial combination of memory cells (with the serial combination commonly being referred to as a NAND string). NAND architecture may be configured in a three-dimensional arrangement comprising vertically-stacked memory cells individually comprising a reversibly programmable vertical transistor. Control or other circuitry may be formed below the vertically-stacked memory cells. Other volatile or non-volatile memory array architectures may also comprise vertically-stacked memory cells that individually comprise a transistor.

Memory arrays may be arranged in memory pages, memory blocks and partial blocks (e.g., sub-blocks), and memory planes, for example as shown and described in any of U.S. Patent Application Publication Nos. 2015/0228651, 2016/0267984, and 2017/0140833. The memory blocks may at least in part define longitudinal outlines of individual wordlines in individual wordline tiers of vertically-stacked memory cells. Connections to these wordlines may occur in a so-called “stair-step structure” at an end or edge of an array of the vertically-stacked memory cells. The stair-step structure includes individual “stairs” (alternately termed “steps” or “stair-steps”) that define contact regions of the individual wordlines upon which elevationally-extending conductive vias contact to provide electrical access to the wordlines.

### BRIEF DESCRIPTION OF THE DRAWINGS

FIGS. 1-7 are diagrammatic cross-sectional views of portions of a construction that will comprise an array of elevationally-extending strings of memory cells in accordance with an embodiment of the invention.

FIGS. 8-20 are diagrammatic sequential sectional and/or enlarged views of the construction of FIGS. 1-7, or portions thereof or alternate and/or additional embodiments, in process in accordance with some embodiments of the invention.

### DETAILED DESCRIPTION OF EXAMPLE EMBODIMENTS

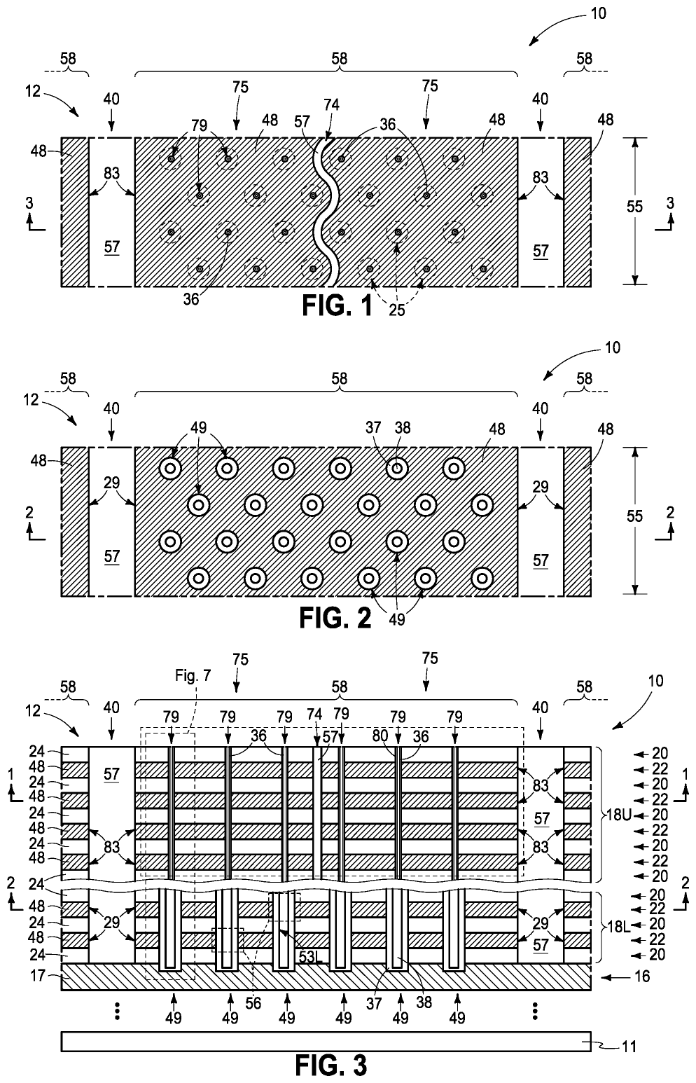

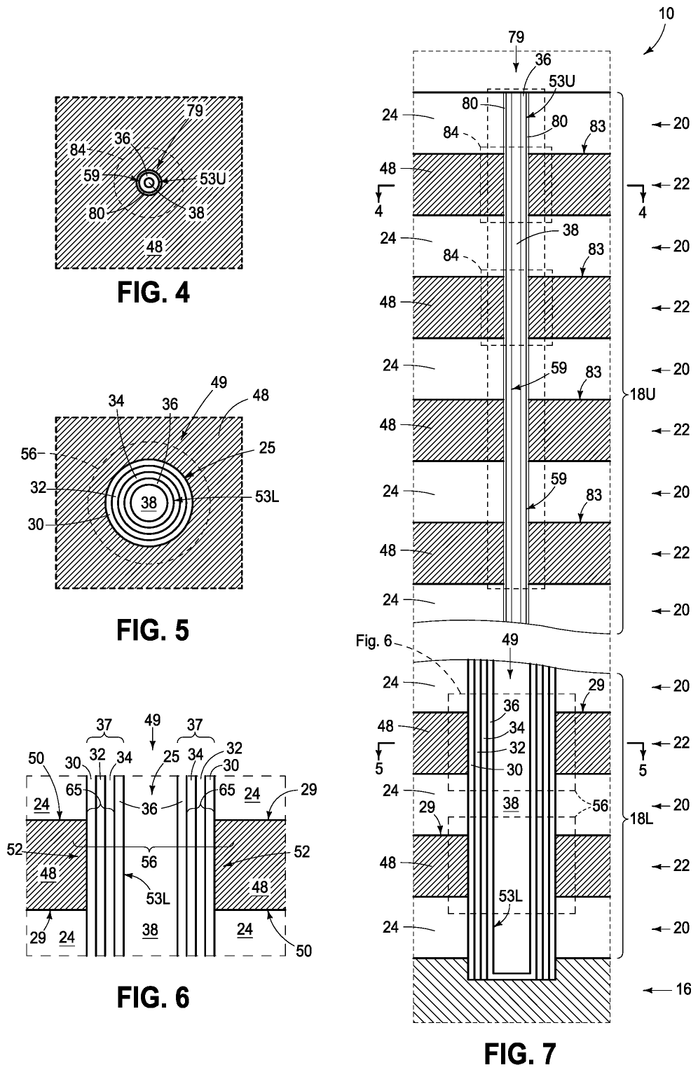

Embodiments of the invention encompass methods used in forming a memory array, for example an array of NAND or other memory cells that may have at least some peripheral control circuitry under the array (e.g., CMOS-under-array). Embodiments of the invention encompass so-called “gate-last” or “replacement-gate” processing, so-called “gate-first” processing, and other processing whether existing or future-developed independent of when transistor gates are formed. Embodiments of the invention also encompass integrated circuitry comprising a memory array comprising strings of memory cells (e.g., NAND architecture) independent of method of manufacture. Example method embodiments are described with reference to FIGS. 1-20.

FIGS. 1-7 show but one example construction 10 having an array or array area 12 in which elevationally-extending strings 49 of transistors and/or memory cells 56 have been formed. Example construction 10 includes a base substrate 11 having any one or more of conductive/conductor/conducting, semiconductive/semiconductor/semiconducting, or insulative/insulator/insulating (i.e., electrically herein) materials. Various materials have been formed elevationally over base substrate 11. Materials may be aside, elevationally inward, or elevationally outward of the FIGS. 1-7-depicted materials. For example, other partially or wholly fabricated components of integrated circuitry may be provided somewhere above, about, or within base substrate 11. Control and/or other peripheral circuitry for operating components within an array (e.g., array 12) of elevationally-extending strings of memory cells may also be fabricated and may or may not be wholly or partially within an array or sub-array. Further, multiple sub-arrays may also be fabricated and operated independently, in tandem, or otherwise relative one another. In this document, a “sub-array” may also be considered as an array.

A conductor tier 16 comprising conductor material 17 (e.g., WSiₓ under conductively-doped polysilicon) is above substrate 11. Conductor tier 16 may comprise part of control circuitry (e.g., peripheral-under-array circuitry and/or a common source line or plate) used to control read and write access to the transistors and/or memory cells in array 12. A stack 18* comprising vertically-alternating insulative tiers 20 and conductive tiers 22 has been formed above conductor tier 16 (an * being used as a suffix to be inclusive of all such same-numerically-designated structures or portions thereof that may or may not have other suffixes). Example thickness for each of tiers 20 and 22 is 20 to 60 nanometers. The example uppermost tier 20 may be thicker/thickest compared to one or more other tiers 20 and/or 22. Only a small number of tiers 20 and 22 is shown, with more likely stack 18* comprising dozens, a hundred or more, etc. of tiers 20 and 22. Other circuitry that may or may not be part of peripheral and/or control circuitry may be between conductor tier 16 and stack 18*. For example, multiple vertically-alternating tiers of conductive material and insulative material of such circuitry may be below a lowest of the conductive tiers 22 and/or above an uppermost of the conductive tiers 22. For example, one or more select gate tiers (not shown) may be between conductor tier 16 and the lowest conductive tier 22. Conductive tiers 22 may not be conductive at this point of processing, for example if “gate-last”/“replacement gate”, and insulative tiers 20 may not be insulative at this point of processing. Regardless, in some embodiments conductive tiers 22 are referred to as first tiers 22 and insulative tiers 20 are referred to as second tiers 20, and which are of different compositions relative one another. Example insulative/second tiers 20 comprise insulative material 24 (e.g., silicon dioxide and/or other material that may be of one or more composition(s)).

Channel openings 25 have been formed (e.g., by etching) through insulative tiers 20 and conductive tiers 22 to conductor tier 16 in a lower portion 18L of stack 18*. Channel openings 25 may taper radially-inward and/or radially-outward (not shown) moving deeper in lower portion 18L of stack 18*. In some embodiments, channel openings 25 may go into conductor material 17 of conductor tier 16 as shown or may stop there-atop (not shown). Alternately, as an example, channel openings 25 may stop atop or within the lowest insulative tier 20. A reason for extending channel openings 25 at least to conductor material 17 of conductor tier 16 is to assure direct electrical coupling of channel material to conductor tier 16 without using alternative processing and structure to do so when such a connection is desired and/or to provide an anchoring effect to material that is within channel openings 25. Etch-stop material (not shown) may be within or atop conductor material 17 of conductor tier 16 to facilitate stopping of the etching of channel openings 25 relative to conductor tier 16 when such is desired. Such etch-stop material may be sacrificial or non-sacrificial. By way of example and for brevity only, channel openings 25 are shown as being arranged in groups or columns of staggered rows of six openings 25 per row and being arrayed in laterally-spaced memory-block regions 58 that will comprise laterally-spaced memory blocks 58 in a finished-circuitry construction. Memory-block regions 58 and resultant memory blocks 58 may be considered as being longitudinally elongated and oriented, for example along a first direction 55. Any alternate existing or future-developed arrangement and construction may be used.

Example memory blocks 58 are shown as at least in part having been defined by horizontally-elongated trenches 40 that were formed (e.g., by anisotropic etching) into stack 18*. Trenches 40 may have respective bottoms that are directly against conductor material 17 (e.g., atop or within) of conductor tier 16 (as shown) or may have respective bottoms that are above conductor material 17 of conductor tier 16 (not shown). Example horizontally-elongated trenches 74 define example sub-blocks 75 in memory blocks 58. Example intervening material 57 is shown in trenches 40 and 74 and provides lateral electrical isolation (insulation) between immediately-laterally-adjacent memory blocks 58 and between immediately-laterally-adjacent sub-blocks 75. Intervening material 57 may include through-array-vias (TAVs, not shown).

Transistor channel material may be formed in the individual channel openings elevationally along the insulative tiers and the conductive tiers, thus comprising individual channel-material strings, which is directly electrically coupled with conductive material in the conductor tier. Individual memory cells of the example memory array being formed may comprise a gate region (e.g., a control-gate region) and a memory structure laterally between the gate region and the channel material. In one such embodiment, the memory structure is formed to comprise a charge-blocking region, storage material (e.g., charge-storage material), and an insulative charge-passage material. The storage material (e.g., floating gate material such as doped or undoped silicon or charge-trapping material such as silicon nitride, metal dots, etc.) of the individual memory cells is elevationally along individual of the charge-blocking regions. The insulative charge-passage material (e.g., a band gap-engineered structure having nitrogen-containing material [e.g., silicon nitride] sandwiched between two insulator oxides [e.g., silicon dioxide]) is laterally between the channel material and the storage material.

The figures show one embodiment wherein charge-blocking material 30, storage material 32, and charge-passage material 34 have been formed in individual channel openings 25. Transistor materials 30, 32, and 34 (e.g., memory-cell materials) may be formed by, for example, deposition of respective thin layers thereof over lower portion 18L of stack 18* (e.g., before forming an upper portion 18U of stack 18*) and within individual channel openings 25 followed by planarizing such back at least to a top surface of lower portion 18L of stack 18*.

Channel material 36 has also been formed in channel openings 25 elevationally along insulative tiers 20 and conductive tiers 22 and comprises individual channel-material strings 53*, in one embodiment having memory-cell materials (e.g., 30, 32, and 34) there-along and with material 24 in insulative tiers 20 being horizontally-between immediately-adjacent channel-material strings 53*. A lower portion 53L of channel-material strings 53* is part of memory-cell strings 49 in the finished-circuitry construction. Materials 30, 32, 34, and 36 of lower portion 53L of channel-material strings 53* are collectively shown as and only designated as material 37 in some figures due to scale. Example channel materials 36 include appropriately-doped crystalline semiconductor material, such as one or more silicon, germanium, and so-called III/V semiconductor materials (e.g., GaAs, InP, GaP, and GaN). Example thickness for each of materials 30, 32, 34, and 36 is 25 to 100 Angstroms. Punch etching may be conducted as shown to remove materials 30, 32, and 34 from the bases of channel openings 25 to expose conductor tier 16 such that channel material 36 is directly against conductor material 17 of conductor tier 16. Such punch etching may occur separately with respect to each of materials 30, 32, and 34 (as shown) or may occur collectively with respect to all after deposition of material 34 (not shown). Alternately, and by way of example only, no punch etching may be conducted and channel material 36 may be directly electrically coupled to conductor material 17 of conductor tier 16 by a separate conductive interconnect (not shown). Channel openings 25 are shown as comprising a radially-central solid insulating material 38 (e.g., spin-on-dielectric, silicon dioxide, and/or silicon nitride). Alternately, and by way of example only, the radially-central portion within channel openings 25 may include void space(s) (not shown) and/or be devoid of solid material (not shown).

Example conductive tiers 22 comprise conducting material 48 that is part of individual conductive lines 29 (e.g., wordlines) that are also part of elevationally-extending strings 49 of individual transistors and/or memory cells 56. Conducting material 48 also comprises individual select gates 83 of select-gate transistors 84 in upper portion 18U of stack 18*. Two or more of select gates 83 may be directly electrically coupled, or otherwise electrically coupled, relative one another (not shown). A thin insulative liner (e.g., Al₂O₃ and not shown) may be formed before forming conducting material 48. Approximate locations of transistors and/or memory cells 56 are indicated with a bracket in some figures and some with dashed outlines in some figures, with transistors and/or memory cells 56 being essentially ring-like or annular in the depicted example. Alternately, transistors and/or memory cells 56 may not be completely encircling relative to individual channel openings 25 such that each channel opening 25 may have two or more elevationally-extending strings 49 (e.g., multiple transistors and/or memory cells about individual channel openings in individual conductive tiers with perhaps multiple wordlines per channel opening in individual conductive tiers, and not shown). Conducting material 48 may be considered as having terminal ends 50 corresponding to control-gate regions 52 of individual transistors and/or memory cells 56. Control-gate regions 52 in the depicted embodiment comprise individual portions of individual conductive lines 29. Materials 30, 32, and 34 may be considered as a memory structure 65 that is laterally between control-gate region 52 and channel material 36.

A charge-blocking region (e.g., charge-blocking material 30) is between storage material 32 and individual control-gate regions 52. A charge block may have the following functions in a memory cell: In a program mode, the charge block may prevent charge carriers from passing out of the storage material (e.g., floating-gate material, charge-trapping material, etc.) toward the control gate, and in an erase mode the charge block may prevent charge carriers from flowing into the storage material from the control gate. Accordingly, a charge block may function to block charge migration between the control-gate region and the storage material of individual memory cells. An example charge-blocking region as shown comprises insulator material 30. By way of further examples, a charge-blocking region may comprise a laterally (e.g., radially) outer portion of the storage material (e.g., material 32) where such storage material is insulative (e.g., in the absence of any different-composition material between an insulative storage material 32 and conducting material 48). Regardless, as an additional example, an interface of a storage material and conductive material of a control gate may be sufficient to function as a charge-blocking region in the absence of any separate-composition-insulator material 30. Further, an interface of conducting material 48 with material 30 (when present) in combination with insulator material 30 may together function as a charge-blocking region, and as alternately or additionally may a laterally-outer region of an insulative storage material (e.g., a silicon nitride material 32). An example material 30 is one or more of silicon hafnium oxide and silicon dioxide.

Upper portion 18U of stack 18* comprises an upper portion 53U of channel-material strings 53* (e.g., comprising channel material 36). Channel material 36 of upper portion 53U of channel-material strings 53* is part of individual select-gate transistors 84 in the finished-circuitry construction. Select-gate transistors 84 may be of the same construction as memory cells 56/transistors 56 (not shown) or may be of different construction therefrom (e.g., as shown). Example upper portions 53U of channel-material strings 53* are in upper channel openings 79 that have previously been lined with a gate insulator 80 (e.g., silicon dioxide). Upper portion 53U of channel-material strings 53* individually comprise a cylinder 59 comprising channel material 36 of individual select-gate transistors 84. In one embodiment, insulating material (e.g., 38) is radially within cylinder 59. Individual upper portions 53U of channel-material strings 53* are ideally directly electrically coupled to individual lower portions 53L of channel-material strings 53* through a conductive structure/plug (not shown).

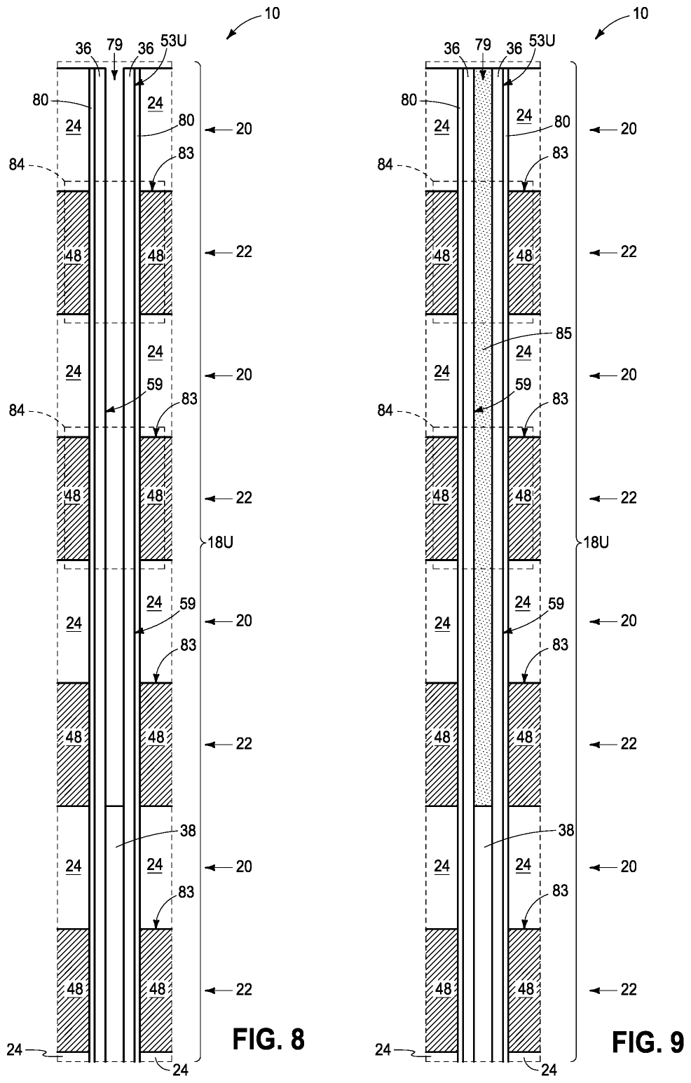

Referring to FIG. 8, such shows an enlarged portion of upper portion 18U of stack 18* showing a single opening 79 and processing subsequent to that shown by FIGS. 1-7 in accordance with one method embodiment. Insulating material 38 has been vertically recessed selectively relative to channel material 36 of cylinder 59 within opening 79 (at least one opening 79) in which cylinder 59 and insulating material 38 are received. Such may occur, by way of example, by masking those openings 79 where such vertical recessing is not desired while leaving other openings 79 exposed, followed by etching insulating material 38 to vertically recess it in exposed openings 79.

Referring to FIG. 9, a mid-material 85 has been formed in opening 79 atop recessed insulating material 38 within an internal volume of cylinder 59 radially-inside of channel material 36. Mid-material 85 comprises conductivity-increasing dopant therein (e.g., one of n-type dopant [e.g., phosphorus, arsenic, antimony, bismuth, and/or lithium] or p-type dopant [e.g., boron, aluminum, gallium, and/or indium]).

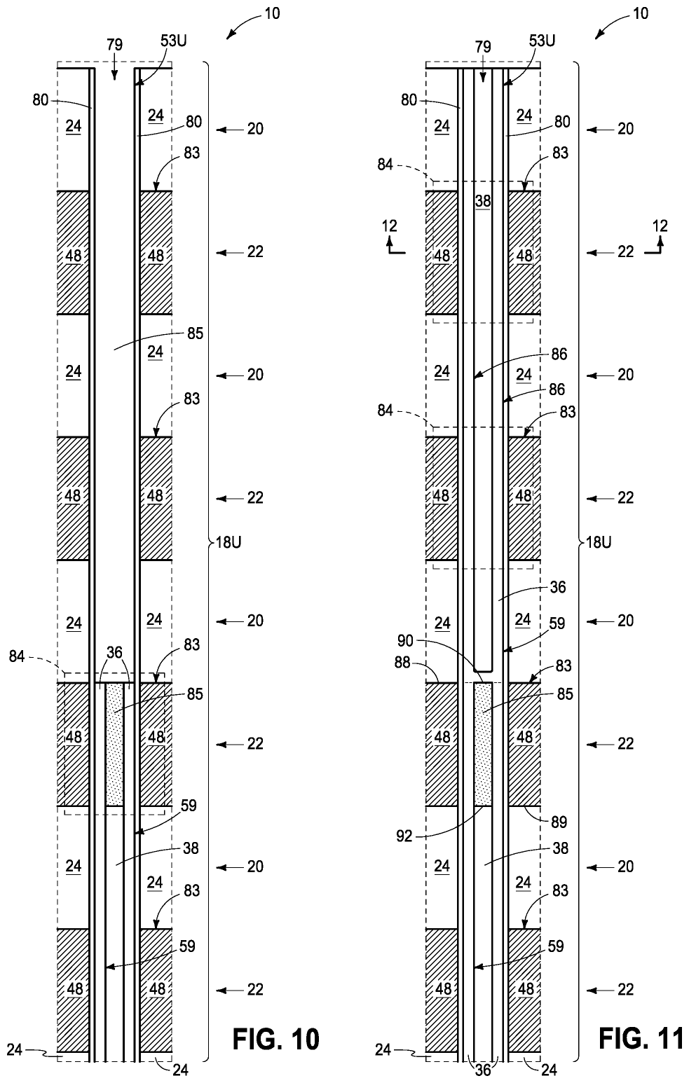

Referring to FIG. 10, mid-material 85 has been vertically recessed within opening 79 (e.g., by etching). Channel material 36 of cylinder 59 may also be vertically recessed as shown (e.g., by etching), for example if channel material 36 and mid-material 85 are of the same etchable composition(s). Alternately, channel material 36 of cylinder 59 may not be vertically recessed (not shown), for example if channel material 36 and mid-material 85 are of different etchable compositions and mid-material 85 is etched selectively relative to channel material 36.

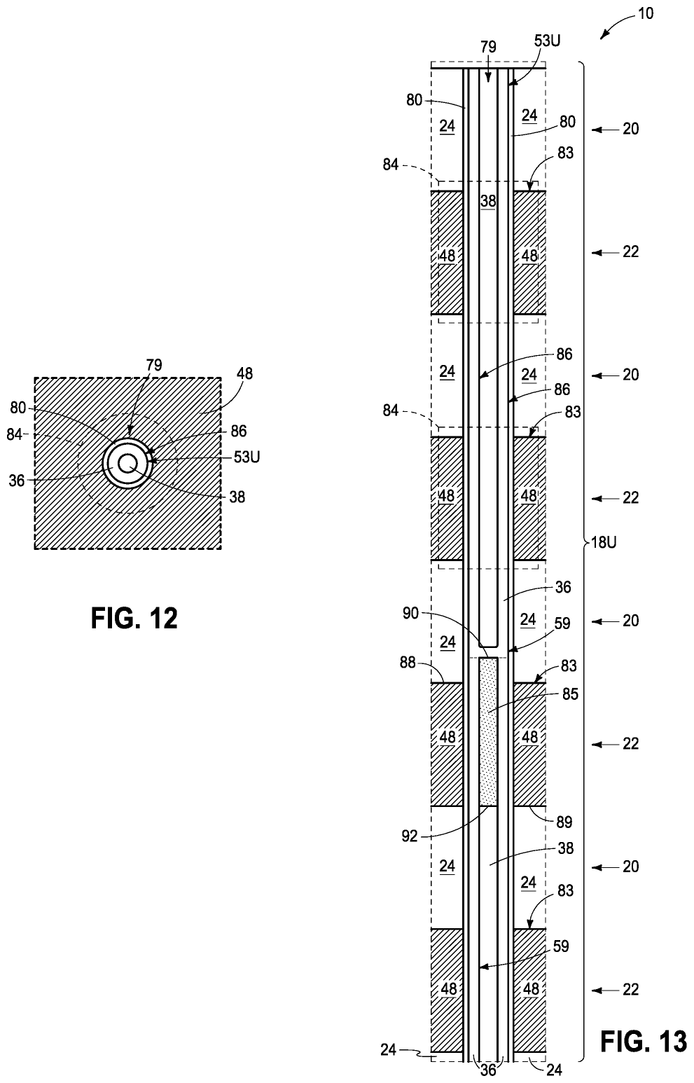

Referring to FIGS. 11 and 12, more channel material (e.g., 36) has been formed in opening 79 atop and directly against vertically-recessed channel material 36. In one such embodiment, the more channel material 36 comprises another cylinder 86 and more insulating material (e.g., 38) has then been formed within opening 79 within another cylinder 86 directly above vertically-recessed mid-material 85.

Conductivity-increasing dopant is out-diffused from mid-material 85 into channel material 36 of cylinder 59 (which is also part of individual select-gate transistors 84). Mid-material 84 is insulative or semiconductive in the finished-circuitry construction (i.e., after the act of out-diffusing). Such out-diffusing into channel material 36 may be used to optimize or better or consistently set the desired threshold voltage (V t) of different select-gate transistors 84 and which may desirably have different Vₜ's relative one another. By way of example only, the out-diffusing of the conductivity-increasing dopant can be caused by exposing mid-material 85 to 800° C. to 1,000° C. for 1 second to 10 seconds. Some out-diffusing of the conductivity-increasing dopant may occur during deposition of mid-material 85 (FIG. 9) and/or during vertical recessing thereof (FIG. 10). However, ideally, the vertically recessing of mid-material 85 within opening 79 occurs prior to at least a majority of the out-diffusing of the conductivity-increasing dopant to better control concentration location for best Vₜ control. In one embodiment, concentration of the conductivity-increasing dopant in mid-material 85 before and after the out-diffusing is 1×10¹⁸ atoms/cm³ to 1×10^{20.5} atoms/cm³, and in one such ideal embodiment is 1×10^{18.5} atoms/cm³ to 1×10^{20.5} atoms/cm³ before and 1×10¹⁸ atoms/cm³ to 1×10²⁰ atoms/cm³ after.

In one embodiment, channel material 36 of upper portion 53U of channel-material strings 53* is of the same composition as that of mid-material 85 but for one of quantity or presence of the conductivity-increasing dopant. In another embodiment, channel material 36 of upper portion 53U of channel-material strings 53* is of different composition from that of mid-material 85 but for at least one of quantity or presence of the conductivity-increasing dopant. By way of example only, example mid-materials are at least one of polysilicon, silicon dioxide, silicon nitride, germanium, aluminum oxide, aluminum nitride, hafnium oxide, and titanium oxide (having an appropriate concentration of conductivity-increasing dopant therein).

In the example methods, one can control the placement of the bottom of mid-material 85 by the degree which insulating material 38 within cylinder 59 is vertically recessed (e.g., as shown by FIG. 8). Analogously, one can control the placement of the top of mid-material 85 by the degree which mid-material 58 within cylinder 59 is vertically recessed (e.g., as shown by FIG. 10). FIG. 11 shows but one example and likely some multiple of openings 79 would be opened and others covered to result in the construction shown by FIG. 11, by way of example. Likewise, one or multiple other openings 79 would likely be processed differently to result in different constructions. Vertical expanse and positioning of mid-material 85 can be controlled by the artisan depending on the result desired, as well as type, composition, and quantity of conductivity-enhancing dopant in mid-material 85. Analogously, predominant composition of mid-material 85 can be the same or different in different openings 79 (e.g., such predominant composition ignoring dopant quantity). By way of examples only, FIGS. 13-19 show some example different mid-material-85 constructions.

In one embodiment, first tiers 22 in upper portion 18U of stack 18* comprise select gates 83 of select-gate transistors 84 in the finished-circuitry construction. Mid-material 85 within individual cylinders 59 is laterally-adjacent at least one of such first tiers 22 and has at least one of a top 90 or a bottom 92 that is between immediately-vertically-adjacent of first tiers 22 in upper portion 18U of stack 18* (FIGS. 11 and 13-15) (i.e., there being no other first tier 22 vertically-between those that are immediately-vertically-adjacent one another). In one embodiment, the at least one of the top or the bottom is top 90 (FIGS. 11 and 13-15) and in one embodiment the at least one of the top or the bottom is bottom 92 (FIGS. 11 and 13-15).

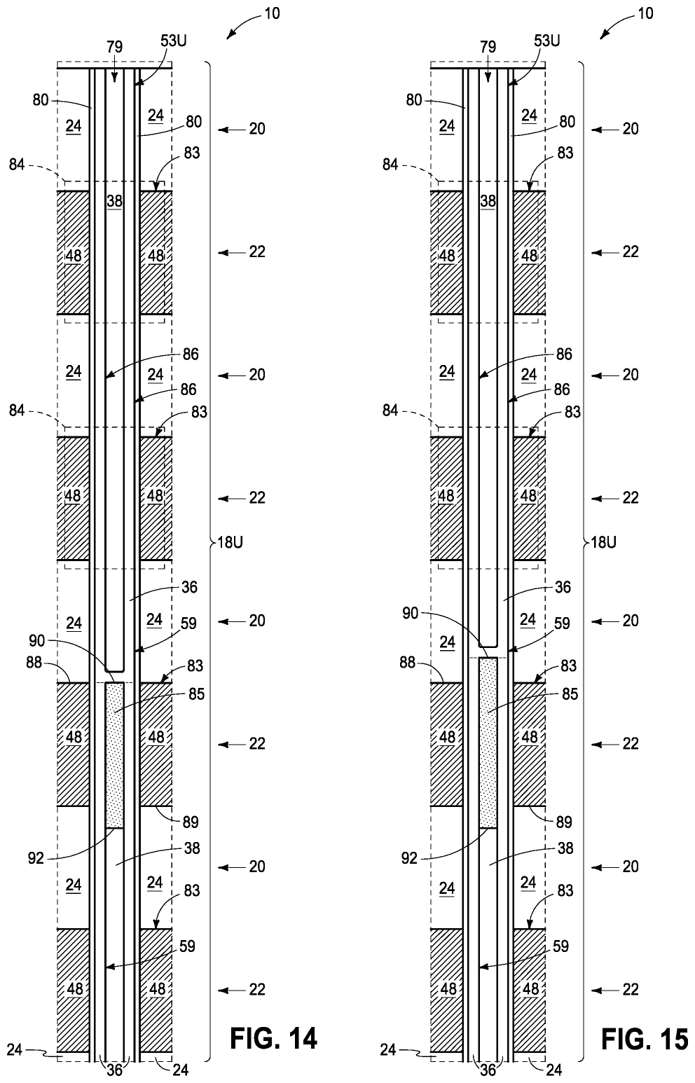

In one embodiment, first tiers 22 in upper portion 18U of stack 18* comprise select gates 83 of select-gate transistors 84 in the finished-circuitry construction. Mid-material 85 within individual cylinders 59 is laterally-adjacent only one of such first tiers 22 (FIGS. 11 and 13-15). In one embodiment, mid-material 85 within individual cylinders 59 has a top 90 that is elevationally-coincident with a top 88 of said only one first tier 22 (FIGS. 11 and 14). In one embodiment, mid-material 85 within individual cylinders 59 has a bottom 92 that is elevationally-coincident with a bottom 89 of said only one first tier 22 (FIGS. 11 and 13).

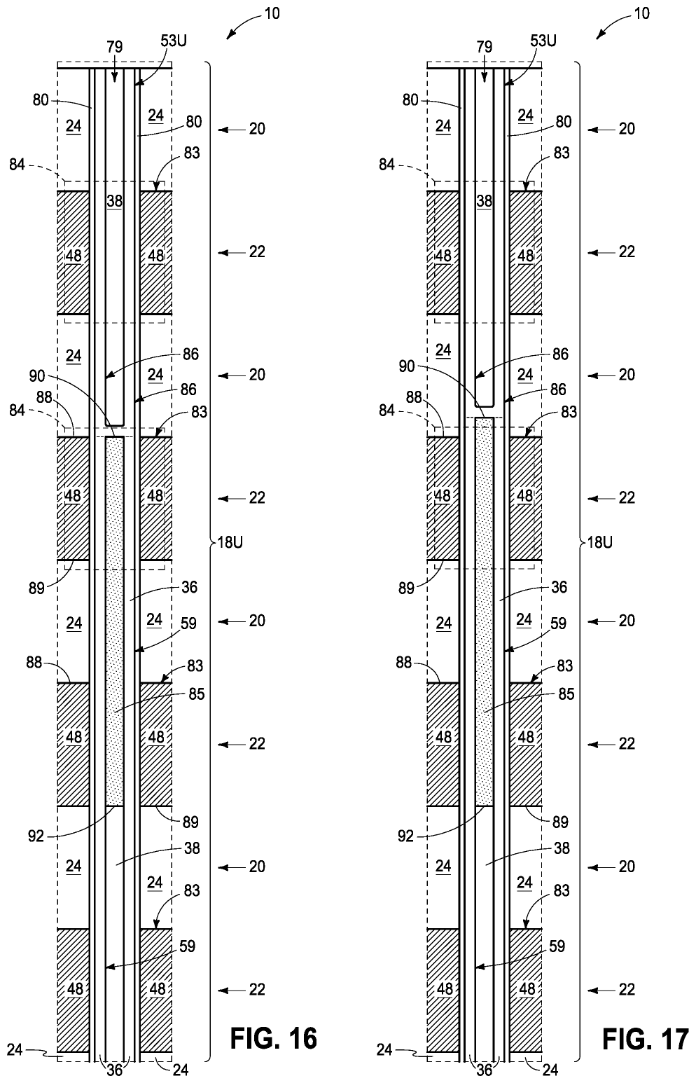

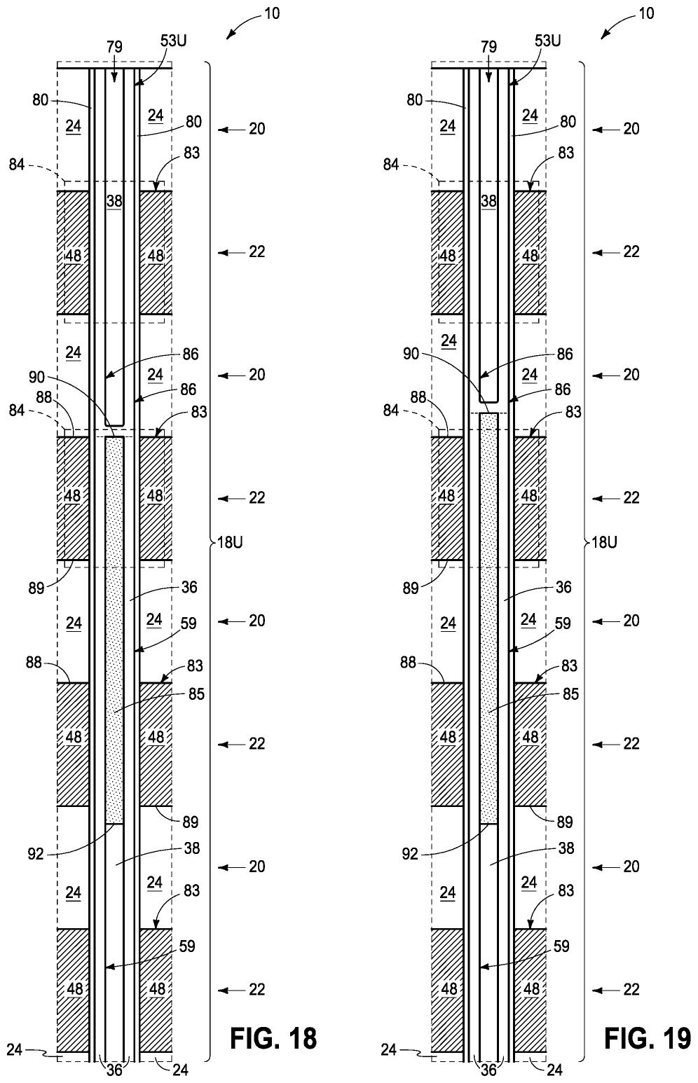

In one embodiment, first tiers 22 in upper portion 18U of stack 18* comprise select gates 83 of select-gate transistors 84 in the finished-circuitry construction. Mid-material 85 within individual cylinders 59 is laterally-adjacent multiple of such first tiers 22 (FIGS. 16-19). In one embodiment, mid-material 85 within individual cylinders 59 has a top 90 that is elevationally-coincident with a top 88 of an uppermost of said multiple first tiers (FIGS. 16 and 18). In one embodiment, mid-material 85 within individual cylinders 59 has a bottom 92 that is elevationally-coincident with a bottom 89 of a lowest of said multiple first tiers (FIGS. 16 and 17). In one embodiment, mid-material 85 has at least one of a top 90 or a bottom 92 that is between immediately-vertically-adjacent of first tiers 22 in upper portion 18U of stack 18* (FIGS. 17-19).

In one embodiment, first tiers 22 in upper portion 18U of stack 18* comprise select gates 83 of select-gate transistors 84 in the finished-circuitry construction. Mid-material 85 within individual of some cylinders 59 is laterally-adjacent only one of such first tiers 22 (FIGS. 11 and 13-15) and mid-material 85 within individual of another some cylinders 59 is laterally-adjacent multiple of such first tiers 22 (FIGS. 16-19). In other words, the finished-circuitry construction could have both a multiple of one or more of what is shown by way of examples in FIGS. 11 and 13-15 as the “some cylinders” and a multiple of one or more of what is shown by way of examples in FIGS. 16-19 as the “another some cylinders”.

In one embodiment, insulating material 38 is within internal volume of the cylinder in the finished-circuitry construction (e.g., cylinder 59 and cylinder 86 in combination being a cylinder 59/86). Insulating material 38 is at least one (a) or (b), where:

(a): directly above a top 90 of mid-material 85; and

(b): directly below a bottom 92 of mid-material 85. Such insulating material 38 that is at least one of the (a) or the (b) has less, if any, of the conductivity-increasing dopant therein as compared to that which is in mid-material 85. In one embodiment, insulating material 38 comprises the (a), in one such embodiment such insulating material 38 not being directly against top 90, for example being separated therefrom by channel material 36. In one embodiment, insulating material 38 comprises the (b) and in one such embodiment such insulating material 38 is directly against bottom 92. In one embodiment, the at least one of the (a) and the (b) is devoid of the conductivity-increasing dopant (devoid herein meaning from 0 atom/cm³ to less than 1×10¹¹ atom/cm³).

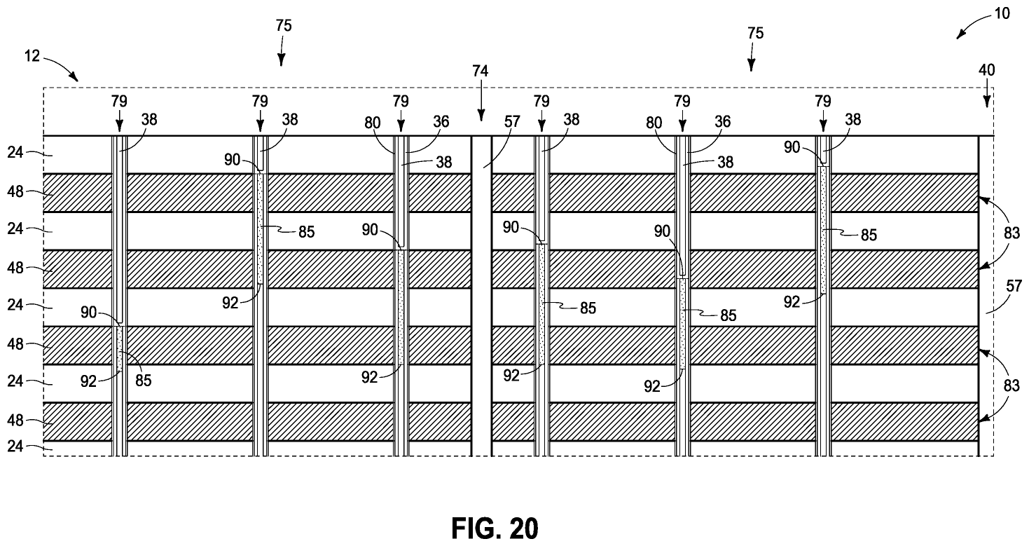

FIG. 20 shows but one example finished-circuitry construction having a combination of a sampling of the constructions of FIGS. 11 and 13-19 or constructions analogous thereto. Position of mid-material 85 could of course be with respect to different-elevation select gates 83 than those which are shown, more than two immediately-adjacent select gates 83 may be vertically-spanned by mid-material 85, and more or less than the four conductive tiers 22 shown may be in upper portion 18U. A conductive plug (not shown) may be atop or radially inward of and, regardless, directly against cylinder 86 at its top for better electrical connection to other components (not shown) of integrated circuitry above the depicted construction and which are not material to the inventions disclosed herein.

Heretofore, setting conductivity-enhancing dopant concentration in the channel material of different-elevation select-gate transistors is largely accomplished by ion implanting such conductivity-enhancing dopants. Such can cause damage to the gate insulator of the select-gate transistors. Further, it can be challenging to control vertical-spread of such conductivity-enhancing dopants resulting from ion implanting. Such problems might be reduced or avoided in accordance with method embodiments of the invention.

Any other attribute(s) or aspect(s) as shown and/or described herein with respect to other embodiments may be used in the embodiments shown and described with reference to the above embodiments.

In one embodiment, a method used in forming memory circuitry (e.g., 10) comprises forming a stack (e.g., 18*) comprising vertically-alternating different-composition first tiers (e.g., 22) and second tiers (e.g., 20). Channel-material strings (e.g., 53*) extend through the first and second tiers. The channel material (e.g., 36) of an upper portion (e.g., 53U) of the channel-material strings is part of individual select-gate transistors (e.g., 84) in a finished-circuitry construction. A lower portion (e.g., 53L) of the channel-material strings is part of memory-cell strings (e.g., 49) in the finished-circuitry construction. The upper portion of the channel-material strings individually comprise a cylinder (e.g., 59) comprising the channel material of the individual select-gate transistors. Mid-material (e.g., 85) is formed within an internal volume of the cylinder radially-inside of the channel material. The mid-material material comprises conductivity-increasing dopant therein. The conductivity-increasing dopant is out-diffused from the mid-material into the channel material of the cylinder and the individual select-gate transistors. The mid-material is insulative or semiconductive in the finished-circuitry construction. Any other attribute(s) or aspect(s) as shown and/or described herein with respect to other embodiments may be used.

Alternate embodiment constructions may result from method embodiments described above, or otherwise. Regardless, embodiments of the invention encompass memory arrays independent of method of manufacture. Nevertheless, such memory arrays may have any of the attributes as described herein in method embodiments. Likewise, the above-described method embodiments may incorporate, form, and/or have any of the attributes described with respect to device embodiments.

In one embodiment, memory circuitry (e.g., 10) comprises a stack (e.g., 18*) comprising vertically-alternating insulative tiers (e.g., 20) and conductive tiers (e.g., 22). Channel-material strings (e.g., 53*) extend through the insulative tiers and the conductive tiers. The channel material (e.g., 36) of an upper portion (e.g., 53U) of the channel-material strings is part of individual select-gate transistors (e.g., 84). A lower portion (e.g., 53L) of the channel-material strings is part of memory-cell strings (e.g., 49). The upper portion of the channel-material strings individually comprise a cylinder (e.g., 59) comprising the channel material of the individual select-gate transistors. A mid-material (e.g., 85) is within an internal volume of the cylinder radially-inside of the channel material. The mid-material material comprises conductivity-increasing dopant therein and is insulative or semiconductive. Insulating material (e.g., 38) is in the internal volume of the cylinder. The insulating material is at least one (a) or (b), where:

(a): directly above a top (e.g., 90) of the mid-material; and

(b): directly below a bottom (e.g., 92) of the mid-material. The insulating material that is at least one of the (a) or the (b) has less, if any, of the conductivity-increasing dopant therein as compared to that which is in the mid-material. Any other attribute(s) or aspect(s) as shown and/or described herein with respect to other embodiments may be used.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming memory circuitry comprises forming a stack comprising vertically-alternating different-composition first tiers and second tiers. Channel-material strings extend through the first and second tiers. The channel material of an upper portion of the channel-material strings is part of individual select-gate transistors in a finished-circuitry construction. A lower portion of the channel-material strings is part of memory-cell strings in the finished-circuitry construction. The upper portion of the channel-material strings individually comprise a cylinder comprising the channel material of the individual select-gate transistors. A mid-material is formed within an internal volume of the cylinder radially-inside of the channel material. The mid-material material comprises conductivity-increasing dopant therein. The conductivity-increasing dopant is out-diffused from the mid-material into the channel material of the cylinder and the individual select-gate transistors. The mid-material is insulative or semiconductive in the finished-circuitry construction.

In some embodiments, a method used in forming memory circuitry comprises forming a stack comprising vertically-alternating different-composition first tiers and second tiers. Channel-material strings extend through the first and second tiers. The channel material of an upper portion of the channel-material strings is part of individual select-gate transistors in a finished-circuitry construction. A lower portion of the channel-material strings is part of memory-cell strings in the finished-circuitry construction. The upper portion of the channel-material strings individually comprise a cylinder comprising the channel material of the individual select-gate transistors. Insulating material is radially within the cylinder. The insulating material is vertically recessed selectively relative to the channel material of the cylinder within an opening in which the cylinder and the insulating material are received. A mid-material is formed in the opening atop the recessed insulating material within an internal volume of the cylinder radially-inside of the channel material. The mid-material material comprises conductivity-increasing dopant therein. The conductivity-increasing dopant is out-diffused from the mid-material into the channel material of the cylinder and the individual select-gate transistors. The mid-material is insulative or semiconductive in the finished-circuitry construction.

In some embodiments, memory circuitry comprises a stack comprising vertically-alternating insulative tiers and conductive tiers. Channel-material strings extend through the insulative tiers and the conductive tiers. The channel material of an upper portion of the channel-material strings is part of individual select-gate transistors. A lower portion of the channel-material strings is part of memory-cell strings. The upper portion of the channel-material strings individually comprise a cylinder comprising the channel material of the individual select-gate transistors. A mid-material is within an internal volume of the cylinder radially-inside of the channel material. The mid-material material comprises conductivity-increasing dopant therein and is insulative or semiconductive. Insulating material is within the internal volume of the cylinder. The insulating material is at least one (a) or (b), where: (a): directly above a top of the mid-material; and (b): directly below a bottom of the mid-material. The insulating material that is at least one of the (a) or the (b) has less, if any, of the conductivity-increasing dopant therein as compared to that which is in the mid-material.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming a stack comprising vertically-alternating different-composition first tiers and second tiers, channel-material strings extending through the first and second tiers, the channel material of an upper portion of the channel-material strings being part of individual select-gate transistors in a finished-circuitry construction, a lower portion of the channel-material strings being part of memory-cell strings in the finished-circuitry construction, the upper portion of the channel-material strings individually comprising a cylinder comprising the channel material of the individual select-gate transistors;
forming a mid-material within an internal volume of the cylinder radially-inside of the channel material, the mid-material material comprising conductivity-increasing dopant therein; and
out-diffusing the conductivity-increasing dopant from the mid-material into the channel material of the cylinder and the individual select-gate transistors, the mid-material being insulative or semiconductive in the finished-circuitry construction.

2. The method of claim 1 wherein concentration of the conductivity-increasing dopant in the mid-material before and after the out-diffusing is 1×10¹⁸ atoms/cm³ to 1×10^{20.5} atoms/cm³.

3. The method of claim 2 wherein the concentration of the conductivity-increasing dopant in the mid-material before the out-diffusing is 1×10^{18.5} atoms/cm³ to 1×10^{20.5} atoms/cm³ and after the out-diffusing is 1×10¹⁸ atoms/cm³ to 1×10²⁰ atoms/cm³.

4. The method of claim 1 wherein the channel material of the upper portion of the channel-material strings is of the same composition as that of the mid-material but for one of quantity or presence of the conductivity-increasing dopant.

5. The method of claim 1 wherein the channel material of the upper portion of the channel-material strings is of different composition from that of the mid-material but for at least one of quantity or presence of the conductivity-increasing dopant.

6. The method of claim 1 wherein,
the first tiers in an upper portion of the stack comprise the select gates of the select-gate transistors in the finished-circuitry construction;
the mid-material within individual of the cylinders is laterally-adjacent at least one of the first tiers in the upper portion of the stack; and
the mid-material has at least one of a top or a bottom that is between immediately-vertically-adjacent of the first tiers in the upper portion of the stack.

7. The method of claim 6 wherein the at least one of the top or the bottom is the top.

8. The method of claim 6 wherein the at least one of the top or the bottom is the bottom.

9. The method of claim 1 wherein,
the first tiers in an upper portion of the stack comprise the select gates of the select-gate transistors in the finished-circuitry construction; and
the mid-material within individual of the cylinders is laterally-adjacent only one of the first tiers in the upper portion of the stack.

10. The method of claim 9 wherein the mid-material within the individual cylinders has a top that is elevationally-coincident with a top of said only one first tier.

11. The method of claim 9 wherein the mid-material within the individual cylinders has a bottom that is elevationally-coincident with a bottom of said only one first tier.

12. The method of claim 11 wherein the mid-material within the individual cylinders has a top that is elevationally-coincident with a top of said only one first tier.

13. The method of claim 9 wherein the mid-material has at least one of a top or a bottom that is between immediately-vertically-adjacent of the first tiers in the upper portion of the stack.

14. The method of claim 13 wherein the at least one of the top or the bottom is the top.

15. The method of claim 13 wherein the at least one of the top or the bottom is the bottom.

16. The method of claim 1 wherein,
the first tiers in an upper portion of the stack comprise the select gates of the select-gate transistors in the finished-circuitry construction; and
the mid-material within individual of the cylinders is laterally-adjacent multiple of the first tiers in the upper portion of the stack.

17. The method of claim 16 wherein the mid-material within the individual cylinders has a top that is elevationally-coincident with a top of an uppermost of said multiple first tiers.

18. The method of claim 16 wherein the mid-material within the individual cylinders has a bottom that is elevationally-coincident with a bottom of a lowest of said multiple first tiers.

19. A method used in forming memory circuitry, comprising:
forming a stack comprising vertically-alternating different-composition first tiers and second tiers, channel-material strings extending through the first and second tiers, the channel material of an upper portion of the channel-material strings being part of individual select-gate transistors in a finished-circuitry construction, a lower portion of the channel-material strings being part of memory-cell strings in the finished-circuitry construction, the upper portion of the channel-material strings individually comprising a cylinder comprising the channel material of the individual select-gate transistors, insulating material being radially within the cylinder;
vertically recessing the insulating material selectively relative to the channel material of the cylinder within an opening in which the cylinder and the insulating material are received;
forming a mid-material in the opening atop the recessed insulating material within an internal volume of the cylinder radially-inside of the channel material, the mid-material material comprising conductivity-increasing dopant therein; and
out-diffusing the conductivity-increasing dopant from the mid-material into the channel material of the cylinder and the individual select-gate transistors, the mid-material being insulative or semiconductive in the finished-circuitry construction.

20. Memory circuitry comprising:
a stack comprising vertically-alternating insulative tiers and conductive tiers, channel-material strings extending through the insulative tiers and the conductive tiers, the channel material of an upper portion of the channel-material strings being part of individual select-gate transistors, a lower portion of the channel-material strings being part of memory-cell strings, the upper portion of the channel-material strings individually comprising a cylinder comprising the channel material of the individual select-gate transistors;
a mid-material within an internal volume of the cylinder radially-inside of the channel material, the mid-material material comprising conductivity-increasing dopant therein and being insulative or semiconductive; and
insulating material within the internal volume of the cylinder, the insulating material being at least one (a) or (b), where:
(a): directly above a top of the mid-material; and
(b): directly below a bottom of the mid-material; and
the insulating material that is at least one of the (a) or the (b) having less, if any, of the conductivity-increasing dopant therein as compared to that which is in the mid-material.
